(19) United States
(12) Patent Application Publication
(10) Pub. No.: US 2025/0151492 A1
(43) Pub. Date: May 8, 2025

(54) MICROELECTRONIC DEVICE TRANSFER AND CLEANING WITH UV LASER

(71) Applicant: Coherent LaserSystems GmbH & Co. KG, Göttingen (DE)

(72) Inventor: Rolf SENCZUK, Bovenden (DE)

(73) Assignee: Coherent LaserSystems GmbH & Co. KG, Göttingen (DE)

(21) Appl. No.: 18/836,870

(22) PCT Filed: Feb. 8, 2023
(86) PCT No.: PCT/EP2023/053080

§ 371 Date: Aug. 8, 2024

Related U.S. Application Data
(60) Provisional application No. 63/309,458, filed on Feb. 11, 2022.

(51) Int. Cl. H10H 29/01; B08B 7/00

(52) U.S. Cl. CPC H10H 29/011; B08B 7/0042; B08B 7/0057

(57) ABSTRACT

A method for ultraviolet-laser transfer and cleaning of microelectronic devices includes transferring a microelectronic device from a donor substrate to a receiver substrate, and cleaning the microelectronic device after transfer. Prior to transfer, the microelectronic device is coupled to the donor substrate via a sacrificial layer containing gallium. A first ultraviolet laser beam ablates the sacrificial layer to release the microelectronic device from the donor substrate, leaving behind a gallium residue on the newly exposed surface of the microelectronic device. A second ultraviolet laser beam ablates the gallium residue to clean the microelectronic device. The first and second ultraviolet laser beams may be generated by the same ultraviolet laser. As compared to liquid etching, laser ablation of the gallium residue eliminates a wet-chemistry step and may be performed by the same laser apparatus used for transfer. Laser cleaning is particularly advantageous when the receiver substrate is intolerant to liquid etching.

### CROSS-REFERENCE TO RELATED APPLICATIONS

This application is a U.S. national stage application under 35 U.S.C. § 371 of International Application No. PCT/EP2023/053080, filed Feb. 8, 2023, which claims the priority of U.S. Provisional Application No. 63/309,458, filed Feb. 11, 2022. The entire contents of each priority application is incorporated herein by reference.

### FIELD OF THE DISCLOSURE

The present invention relates in general to substrate-to-substrate transfer of microelectronic devices aided by laser-lift-off ablation of a gallium-nitride layer. The present invention relates in particular to the removal of residual gallium after laser lift-off.

### BACKGROUND OF THE DISCLOSURE

To meet the consumer demand for thinner and lighter electronic devices with higher performance, the microelectronics industry is pushing toward making ever smaller microelectronic devices. For example, micro light-emitting diodes (μLEDs) less than 70 microns×70 microns in size and as small as about 3 microns×3 microns are being developed for the purpose of making high-resolution LED displays. μLED displays are an emerging display technology expected to offer higher brightness, lower power consumption, and faster response than organic LED displays and liquid-crystal displays.

Wafer-level manufacturing has long been the most cost-effective mass-production method for microelectronic devices, with the capability to manufacture millions of identical microelectronic devices simultaneously on the same wafer. Although in some situations it is possible to separate out individual microelectronic devices from a wafer by dicing the wafer, thinner form factors may be achieved by instead detaching the microelectronic devices completely from the wafer. Therefore, wafer-level manufacturing of microelectronic devices may involve one or more steps of detaching the microelectronic devices from a substrate. For example, one type of microelectronic devices (e.g., red LEDs) may be grown at high density on a growth wafer and then detached from the growth wafer to be implemented at lower density on a substrate of a final device (e.g., a color display), possibly in conjunction with other types of microelectronic devices (e.g., blue and green LEDs) grown on other growth wafers. The production of microelectronic devices also often involves processing of both the top and the bottom of the microelectronic devices after growing at least some layers of the microelectronic devices on a growth wafer. Such double-sided processing may require one or more operations of transferring the microelectronic devices from one substrate to another in order to flip them over. Additionally, pick-and-place technology may be used to replace faulty microelectronic devices in an array of microelectronic devices.

Laser lift-off has emerged as a promising transfer technology. The laser lift-off process releases a microelectronic device from a substrate by laser ablating a sacrificial layer located between the substrate and the microelectronic device. Laser lift-off typically utilizes ultraviolet (UV) light generated by an excimer laser, and a microelectronic device may be released from a substrate by a single laser pulse. Laser lift-off may be applied to a single individual microelectronic device, a subset of the total number of microelectronic devices on a substrate, or all microelectronic devices on a substrate. In laser lift-off of multiple microelectronic devices, the laser beam may be scanned across selected portions of a substrate to release microelectronic devices one by one, or a larger-area laser pulse may be applied to multiple microelectronic devices simultaneously. The larger-area laser pulse may be masked to exclusively expose the footprints of the individual microelectronic devices.

Transfer of microelectronic devices may utilize laser lift-off in a stamp-based transfer scheme, a bond-release scheme, or a laser-induced forward transfer scheme. In the stamp-based scheme, microelectronic devices are released from a donor substrate by laser lift-off, and picked up from the donor substrate by an elastomer stamp. The stamp then places the microelectronic devices on a receiver substrate. In the bond-release scheme, the microelectronic devices are bonded to the receiver substrate before being released from the donor substrate. In the laser-induced forward transfer scheme, the receiver substrate is held a distance from the microelectronic devices, and the ablation of the sacrificial layer not only releases the microelectronic devices from the donor substrate but also propels the microelectronic devices across the gap to the receiver substrate. The bond-release and laser-induced forward transfer schemes elegantly eliminate the need for robotic equipment to handle the individual microelectronic devices in the transfer.

The sacrificial layer ablated to release microelectronic devices from the donor substrate in laser lift-off is typically made of gallium nitride (GaN). Laser ablation of GaN produces nitrogen gas and liquid gallium. While all of the nitrogen gas escapes, a residue of liquid gallium remains on the newly exposed surface of the microelectronic device. For most applications, it is necessary to remove this residue since the residue may impede the performance of the microelectronic device or be in the way of subsequent processing of the microelectronic device. In particular, when the microelectronic device is a μLED, the residue may block light emission from the μLED. The gallium residue is usually etched away with a caustic liquid. For example, with an aqueous solution of ammonia (NH₃) or hydrochloric acid (HCl).

### SUMMARY OF THE DISCLOSURE

Disclosed herein is a method for laser-lift-off transfer of microelectronic devices with subsequent laser cleaning of the gallium residue. In this method, both transfer and subsequent cleaning are based on UV laser ablation. First, transfer is initiated by a UV laser beam that ablates the sacrificial GaN layer. After transfer, a UV laser beam ablates the gallium residue. Conveniently, both laser ablation operations may be performed by the same UV laser. The second laser ablation operation to remove the gallium residue replaces conventional etching using a caustic liquid.

The advantages of the present method are multifold. Some substrates are not tolerant to liquid etching. For example, the display backplane of a μLED display may include a polymer or another material that is intolerant to etching with a caustic liquid. Laser cleaning is a viable approach to gallium residue cleaning in caustic-liquid-intolerant scenarios at least because it is possible to apply the UV laser beam selectively to each individual microelectronic device in need of cleaning. The UV laser beam used for cleaning may be sized or masked with relative ease to expose only the microelectronic device(s), and laser-ablation damage to h substrate areas can therefore be avoided. Even in the case of caustic-liquid-tolerant substrates, the present transfer and cleaning method offers convenience and simplicity by eliminating a wet-chemistry step and instead applying a second ablation operation after laser-lift-off transfer. The replacement of liquid etching with laser ablation has the potential to significantly reduce the overall processing time. Additionally, in most scenarios, the laser cleaning step can be performed with the apparatus and functionality already in place for laser lift-off.

In one aspect, a method for ultraviolet-laser transfer and cleaning of microelectronic devices includes a step of transferring a microelectronic device from a first substrate to a second substrate. The microelectronic device is coupled to the first substrate via a sacrificial layer that contains gallium. The transfer step includes releasing the microelectronic device from the first substrate by laser ablating the sacrificial layer with a first ultraviolet laser beam. This laser ablation leaves a gallium residue on the microelectronic device. The method further includes a step of cleaning at least a portion of the gallium residue off the microelectronic device after the transfer step. The cleaning step includes laser ablating the gallium residue with a second ultraviolet laser beam. The sacrificial layer may be a heterogenous solid layer. The method may include generating the first and second ultraviolet laser beams with the same ultraviolet laser.

### BRIEF DESCRIPTION OF THE DRAWINGS

The accompanying drawings, which are incorporated in and constitute a part of the specification, schematically illustrate preferred embodiments of the present invention, and together with the general description given above and the detailed description of the preferred embodiments given below, serve to explain principles of the present invention.

FIGS. 1A-D illustrate a method for ultraviolet-laser transfer and cleaning of microelectronic devices, according to an embodiment.

FIG. 2 illustrates a laser beam configuration for laser cleaning of a plurality of microelectronic devices on a receiver substrate in a multi-device extension of the cleaning step of the FIG. 1 method, according to an embodiment.

FIG. 3 illustrates another laser beam configuration for laser cleaning of a plurality of microelectronic devices on a receiver substrate in a multi-device extension of the cleaning step of the FIG. 1 method, wherein UV irradiation is applied exclusively to the microelectronic devices without exposing adjacent portions of the receiver substrate, according to an embodiment.

FIG. 4 illustrates yet another laser beam configuration for laser cleaning of a plurality of microelectronic devices on a receiver substrate in a multi-device extension of the cleaning step of the FIG. 1 method, also with UV irradiation being exclusively applied to the microelectronic devices without exposing adjacent portions of the receiver substrate, according to an embodiment.

FIG. 5 is an image of microelectronic devices on a substrate that demonstrates the performance of one example of the method of FIG. 1.

### DETAILED DESCRIPTION OF THE DISCLOSURE

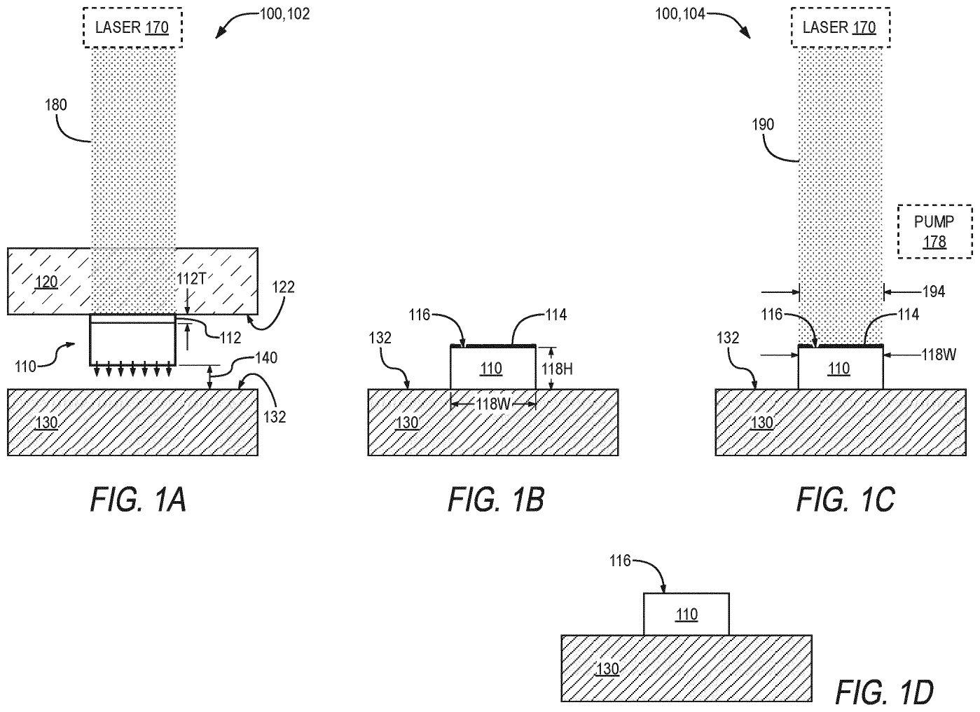

Referring now to the drawings, wherein like components are designated by like numerals, FIGS. 1A-D are cross-sectional views illustrating one method 100 for ultraviolet-laser transfer and cleaning of microelectronic devices. FIG. 1A shows a transfer step 102 of method 100, FIG. 1B shows the result of transfer step 102, FIG. 1C shows a subsequent cleaning step 104 of method 100, and FIG. 1D shows the end result of method 100. In the example depicted in FIGS. 1A-D, method 100 is applied to a single microelectronic device 110. Method 100 is readily extendable to a plurality of devices 110.

Device 110 may be a μLED, a photodiode, a complementary metal oxide semiconductor circuit, or another microelectronic device. The transverse dimensions of device 110, e.g., width 118W indicated in FIG. 1B, may be less than about 100-200 microns and typically, but not necessarily, greater than about 0.1 microns. In one example, width 118W is in the range between 1 and 100 microns. The height 118H of device 110, indicated in FIG. 1B, may be tens of microns or less.

As shown in FIG. 1A, transfer step 102 includes releasing device 110 from a donor substrate 120 by laser lift-off, that is, by laser ablating a sacrificial layer 112 with a UV laser beam 180. Prior to laser lift-off, layer 112 couples device 110 to a surface 122 of donor substrate 120. Layer 112 may be a sacrificial layer of device 110. Layer 112 is made substantially or entirely of GaN. During transfer step 102, donor substrate 120 and receiver substrate 130 are arranged such that surface 122 of donor substrate 120 faces a surface 132 of a receiver substrate 130, with device 110 positioned between surfaces 122 and 132. To effect laser lift-off, UV laser beam 180 is directed through donor substrate 120 to irradiate and ablate layer 112.

UV laser beam 180 may be generated by a UV laser 170, such as an excimer laser. The wavelength of UV laser beam 180 may be less than 320 nanometers (nm) to effectively ablate layer 112, for example in the range between 190 and 320 nm. In one embodiment, UV laser beam 180 is pulsed and transfer step 102 ablates layer 112 with a single pulse of UV laser beam 180. In another embodiment, transfer step 102 ablates layer 112 with a sequence of pulses of UV laser beam 180. The energy density delivered to layer 112 by UV laser beam 180 may be in the range between 600 and 1500 millijoules/centimeter² (mJ/cm²), and layer 112 may have a thickness 112T in the range between 0.5 and 5 nm.

Donor substrate 120 can withstand and is transmissive to UV light. Donor substrate 120 is, for example, made of quartz or sapphire. Receiver substrate 130 may or may not be UV transmissive. In one scenario, receiver substrate 130 is a final device substrate, for example a display backplane. In this scenario, receiver substrate 130 may include or substantially consist of a polymer. The final device substrate, whether a display backplane or not, may also include one or more functional layers. In another scenario, receiver substrate 130 is an intermediate substrate used for further processing of device 110 before transfer to yet another substrate that may be a final device substrate. In this scenario, the material composition of receiver substrate 130 may be similar to that of donor substrate 120 to enable laser transfer of device 110 away from receiver substrate 130. Receiver substrate 130 may be intolerant to caustic-liquid etching, for example due to the presence of a polymer or functional layers.

FIG. 1A depicts a forward-transfer embodiment of transfer step 102. In this forward-transfer embodiment, donor substrate 120 and receiver substrate 130 are arranged such that, while device 110 is still coupled to donor substrate 120, there is a non-zero gap 140 between device 110 and receiver substrate 130. Laser ablation of layer 112 releases device 110 from donor substrate 120 and propels device 110 toward surface 132 of receiver substrate 130. Surface 132 may include an adhesive that bonds device 110 to surface 132 after transfer, or device 110 may rest in place on surface 132 until bonded to surface 132 by, e.g., soldering.

In a bond-release embodiment of transfer step 102, not depicted in FIG. 1A, donor substrate 120 and receiver substrate 130 are arranged such that device 110 is sandwiched between donor substrate 120 and receiver substrate 130 prior to transfer (corresponding to zero gap 140 between device 110 and receiver substrate 130). Laser ablation of layer 112 releases device 110 from donor substrate 120 and leaves device 110 on surface 132 of receiver substrate 130. Device 110 may be bonded to surface 132 prior to laser lift-off from donor substrate 120, for example by an adhesive or soldering. Alternatively, device 110 may rest in place on surface 132 after laser lift-off and until bonded to surface 132 by, e.g., soldering.

Method 100 may also be used in stamp-based transfer schemes. When method 100 is applied to a stamp-based transfer scheme, receiver substrate 130 is a stamp that grabs onto the sides of device 110 (vertical sides in FIG. 1A).

As shown in FIG. 1B, transfer step 102 results in device 110 being coupled to surface 132 of receiver substrate 130. A surface 116 of device 110 faces away from surface 132. Surface 116 was exposed by laser ablation of layer 112 in transfer step 102. However, laser ablation of layer 112 in transfer step 102 leaves a gallium residue 114 on surface 116. At least initially, gallium residue 114 is liquid, as gallium metal has a melting temperature of 30° C. Gallium residue 114 may form a continuous coating on surface 116 (as depicted in FIG. 1B), a collection of droplets, or a combination thereof.

In cleaning step 104, shown in FIG. 1C, a UV laser beam 190 is directed onto surface 116 to ablate gallium residue 114 so as to remove gallium residue 114 from surface 116, as shown in FIG. 1D. The wavelength of UV laser beam 190 may be in the range between 190 and 320 nm, and may be the same as the wavelength of UV laser beam 180. In a particularly advantageous embodiment, each of UV laser beams 180 and 190 is generated by UV laser 170 such that the same laser system performs both transfer step 102 and cleaning step 104. Alternatively, UV laser beam 190 is generated by a different laser source than the laser source used in transfer step 102.

The energy density delivered by UV laser beam 190 in cleaning step 104 may be less than the energy density delivered by UV laser beam 180 in transfer step 102, so as to prevent UV laser beam 190 from ablating or otherwise damaging device 110. In one embodiment of method 100, the energy density delivered by UV laser beam 190 in cleaning step 104 is no more than 85% (e.g., between 25% and 85%) of the energy density delivered by UV laser beam 180 in transfer step 102. In another embodiment, the energy density delivered by UV laser beam 190 in cleaning step 104 is between 500 and 1000 mJ/cm².

Depending on the material of receiver substrate 130 (and any objects disposed on surface 132 other than device 110), it may be preferred or even necessary to restrict irradiation by UV laser beam 190 to surface 116 only. Thus, in one embodiment of cleaning step 104, the transverse size and shape of UV laser beam 190 match the transverse size and shape of surface 116. For example, as shown in FIG. 1C, the width 194 of UV laser beam 190 in the plane of FIG. 1C, matches width 118W of surface 116 in that same plane. UV laser beam 190 may be masked to match the shape of surface 116, e.g., rectangular. UV laser beam 180, in transfer step 102, may be sized and shaped to match the footprint of layer 112 in a similar manner and for similar reasons. Referring again to cleaning step 104, a portion of surface 116 may be particularly optically sensitive, such as a light-emitting or light-collecting area, that is only a subset of surface 116. In such scenarios, UV laser beam 190 may be sized and shaped to avoid illuminating this sensitive portion of surface 116, for example with width 194 being less than width 118W. In other scenarios, applicable to light-emitting or light-collecting embodiments of device 110, an associated light-transmitting area may be only a subset of surface 116. In such scenarios, UV laser beam 190 may be sized and shaped to match the light-transmitting area of surface 116. Also in these scenarios, width 194 may be less than width 118W.

Laser ablation of gallium residue 114 frees gallium residue 114 from surface 116 but may produce gallium particulates or even airborne droplets. To prevent such gallium particulates or airborne droplets from contaminating surface 116 or other portions of receiver substrate 130 (or objects disposed thereon), method 100 may include exhausting the gallium residue freed from surface 116. Thus, in addition to one or more laser sources used for laser ablation in transfer step 102 and cleaning step 104, the apparatus performing method 100 may include a pump 178 that collects and removes freed gallium residue.

Although not shown in FIGS. 1A-D, additional process steps may take place between transfer step 102 and cleaning step 104. In one such extension of method 100, other microelectronic devices are transferred to receiver substrate 130 from other donor substrates, in which case cleaning step 104 may be applied to both device 110 and these other microelectronic devices. In one example, device 110 is a red μLED transferred to receiver substrate 130 from a wafer of red μLEDs, and method 100 further includes applying transfer step 102 to a green μLED on a wafer of green μLEDs and to a blue μLED on a wafer of blue μLEDs, before cleaning step 104 is applied to each of the red, green, and blue μLEDs.

In another extension, method 100 applies transfer step 102 to a plurality of devices 110 on donor substrate 120 to transfer each of these devices 110 to receiver substrate 130, whereafter method 100 may apply cleaning step 104 to each of the transferred devices 110. Optionally, this extension of method 100 further includes transferring other devices 110 from one or more other donor substrates 120 to receiver substrate 130, for example according to transfer step 102, before applying cleaning step 104 to all the transferred devices 110. Alternatively, in scenarios where different types of devices 110 from different respective donor substrates 120 are to be transferred to the same receiver substrate 130, method 100 may complete the transfer and cleaning steps for each type of device 110 before proceeding to transfer and cleaning of the next type of device 110.

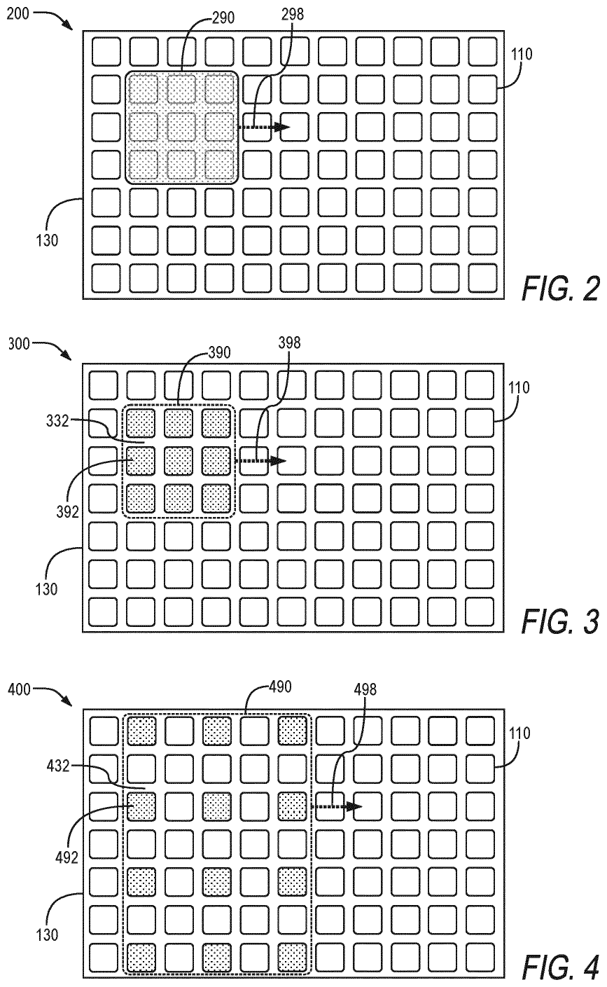

FIG. 2 is a plan view illustrating one laser beam configuration 200 for laser cleaning of a plurality of devices 110 on receiver substrate 130 in a multi-device extension of cleaning step 104 of method 100. In configuration 200, a UV laser beam 290 simultaneously irradiates a group of adjacent devices 110 located on receiver substrate 130. UV laser beam 290 is sized and shaped such that its footprint (shaded area in FIG. 2) on receiver substrate 130 contains the entire group of devices 110, as well as any portion of receiver substrate 130 located between the devices 110. The sizing and shaping of UV laser beam 290 required to attain the desired footprint may include masking. Configuration 200 is suitable when receiver substrate 130 can tolerate the irradiation by UV laser beam 290 required for cleaning of gallium residue 114 on devices 110, or when UV laser damage to receiver substrate 130 is acceptable.

In the example depicted in FIG. 2, the group of devices 110 to be cleaned is a 3×3 array of devices 110. Configuration 200 may be adapted to irradiate a different number of devices 110, even a single device 110. When the group of devices 110 simultaneously irradiated by UV laser beam 290 is only a subset of the total number of devices 110 to be cleaned, UV laser beam 290 may be scanned, for example as indicated by arrow 298, to sequentially clean several groups of devices 110. In this manner, UV laser beam 290 may clean a larger subset of the devices 110 located on receiver substrate 130, or even all devices 110 on receiver substrate 130. UV laser beam 290 may conveniently be moved between pulses thereof. The scanning of UV laser beam 290 may be tailored to skip some devices 110.

FIG. 3 illustrates another laser beam configuration 300 for laser cleaning of a plurality of devices 110 on receiver substrate 130, wherein UV irradiation is applied exclusively to devices 110 without exposing adjacent portions of receiver substrate 130. Configuration 300 is another multi-device extension of cleaning step 104 of method 100. In configuration 300, a group of devices 110 is irradiated by a UV laser beam 390 that is masked to selectively expose only devices 110. UV laser beam 390 consists of a plurality of beam columns 392, indicated as shaded areas in FIG. 3. Each column 392 is aligned to a respective device 110. The portions 332 of receiver substrate 130 located between the devices 110 are not irradiated by UV laser beam 390. Configuration 300 is otherwise similar to configuration 200 and may be applied in a scanning fashion as discussed above in reference to FIG. 2, for example as indicated by arrow 398. Configuration 300 is preferable over configuration 200 when direct irradiation of receiver substrate 130 with the energy density required for cleaning of devices 110 would cause unacceptable damage to receiver substrate 130.

FIG. 4 illustrates yet another laser beam configuration 400 for laser cleaning of a plurality of devices 110 on receiver substrate 130, also with UV irradiation being exclusively applied to devices 110 without exposing adjacent portions of receiver substrate 130. Configuration 400 is a modification of configuration 300 using a UV laser beam 490 consisting of a plurality of beam columns 492 (indicated as shaded areas in FIG. 4) spaced apart to irradiate a less dense array of devices 110 than the full array of devices 110 on receiver substrate 130. In the example depicted in FIG. 4, the density of the array of devices 110 irradiated by UV laser beam 490 is 25% of the density of the full array of devices 110 on receiver substrate 130, with columns 492 aligned with one device 110 in every 2×2 block of devices 110. Portions 432 of receiver substrate 130 not occupied by devices 110 are not exposed to UV laser beam 490, and devices 110 not intended to be cleaned are also not exposed to UV laser beam 490. UV laser beam 490 may be applied in a scanning fashion as discussed above in reference to FIG. 2, for example as indicated by arrow 498.

The degree of selectivity of cleaning exemplified by FIGS. 2, 3, and 4, is not achievable with liquid etching and demonstrates a significant advantage of the present transfer and cleaning methods. Furthermore, some existing laser lift-off systems are equipped with the functionality to shape, size, mask, and scan a UV laser beam as discussed above in reference to FIGS. 2, 3, and 4, and it may therefore be possible to achieve these UV laser beam configurations with existing equipment. Although discussed in the context of cleaning step 104, each of the configurations discussed above in reference to FIGS. 2, 3, and 4 may be applied also to transfer step 102.

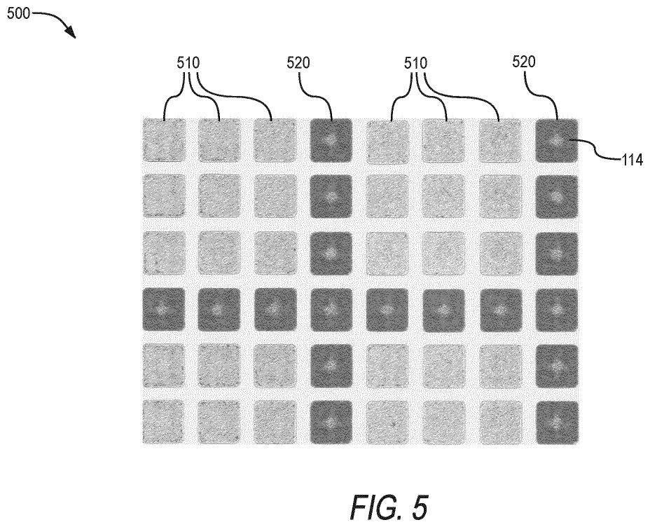

FIG. 5 is an image 500 of microelectronic devices that demonstrates the performance of method 100 in one example. Image 500 is a transmission image of an array of microelectronic devices on a receiver substrate after transfer according to transfer step 102 of method 100, and including (a) microelectronic devices 510 that have been cleaned according to cleaning step 104 of method 100 and (b) microelectronic devices 520 that have not been cleaned. Not all devices 510 and 520 are labeled in FIG. 5, but devices 520 are readily identifiable as the dark devices in image 500. The darkness of devices 520 stems from gallium residue 114 blocking light transmission through the devices. In contrast, light is transmitted by devices 510, thus demonstrating the efficacy of cleaning step 104.

In the image 500 example, each device 510 was cleaned by a single laser pulse with a wavelength of 248 nm and an energy density of 900 mJ/cm². The energy density needed for cleaning of gallium residue 114 may depend on several factors. One such factor is the thickness of the sacrificial GaN layer ablated in the transfer step (thickness 112T of layer 112 in FIG. 1A). Another factor is the level of cleaning required in a given application. Some applications may require a high level of cleaning, while others may be able to tolerate some amount of gallium residue remaining after the laser cleaning step. For example, removal of 80-99% of the gallium residue may be acceptable in some applications, and the cleaning for these applications can therefore be performed with a lower laser energy density than when higher level of cleaning is required. We have found that the process window for removal of about 99% of the gallium residue is usually fairly wide. In one example, we have found that this level of cleaning can be achieved with laser energy densities in the range between 700 and 900 mJ/cm².

Currently, the majority of laser lift-off processes are based on ablation of a sacrificial GaN layer. However, the sacrificial layer may have other compositions, such as aluminum gallium nitride (AlₓGa₁₋ₓN), gallium oxide (Ga₂O₃), amorphous gallium oxide (α-GaOₓ), or indium gallium nitride (InₓGa₁₋ₓN). Method 100 is extendable to these compositions. Thus, more generally, layer 112 is a heterogeneous solid layer that contains gallium, and gallium residue 114 is a residue that contains gallium and possible other metals as well.

The present invention is described above in terms of a preferred embodiment and other embodiments. The invention is not limited, however, to the embodiments described and depicted herein. Rather, the invention is limited only by the claims appended hereto.

What is claimed is:

1. A method for ultraviolet-laser transfer and cleaning of microelectronic devices, comprising steps of:
transferring a microelectronic device from a first substrate to a second substrate, the microelectronic device being coupled to the first substrate via a sacrificial layer, the sacrificial layer being a heterogenous solid layer containing gallium, said transferring including releasing the microelectronic device from the first substrate by laser ablating the sacrificial layer with a first ultraviolet laser beam, said laser ablating leaving a gallium residue on the microelectronic device; and
cleaning at least a portion of the gallium residue off the microelectronic device after the transferring step, said cleaning including laser ablating the gallium residue with a second ultraviolet laser beam.

2. The method of claim 1, wherein the sacrificial layer contains gallium nitride.

3. The method of claim 1, wherein the sacrificial layer is made of gallium nitride.

4. The method of claim 1, further comprising generating the first and second ultraviolet laser beams with the same ultraviolet laser.

5. The method of claim 4, wherein the ultraviolet laser is an excimer laser.

6. The method of claim 1, wherein the first substrate is a sapphire substrate and the first and second ultraviolet laser beams have a wavelength of between 190 and 320 nanometers.

7. The method of claim 1, wherein the cleaning step further includes exhausting the gallium residue freed from the microelectronic device by laser ablation.

8. The method of claim 1, wherein the cleaning step is performed by a single ultraviolet laser pulse.

9. The method of claim 1, wherein the energy density of the second ultraviolet laser beam incident on the microelectronic device in the cleaning step is less than the energy density of the first ultraviolet laser beam incident on the sacrificial layer in the transferring step.

10. The method of claim 1, wherein the energy density of the second ultraviolet laser beam incident on the microelectronic device in the cleaning step is between 25% and 85% of the energy density of the first ultraviolet laser beam incident on the sacrificial layer in the transferring step.

11. The method of claim 1, wherein the transferring step results in the microelectronic device being situated on the second substrate with a laser ablated side of the microelectronic device farthest from the second substrate.

12. The method of claim 1, wherein the second substrate is a display backplane.

13. The method of claim 1, wherein the second substrate includes a polymer.

14. The method of claim 1, wherein the second substrate includes a functional layer.

15. The method of claim 1, further comprising applying the cleaning step to a plurality of microelectronic devices situated on the second substrate.

16. The method of claim 15, further comprising simultaneously irradiating the plurality of microelectronic devices with the second ultraviolet laser beam to clean the gallium residue off each of the plurality of microelectronic devices.

17. The method of claim 15, further comprising spatially scanning the second ultraviolet laser beam to sequentially irradiate the plurality of microelectronic devices, so as to clean the gallium contamination off the plurality of microelectronic devices sequentially.

18. The method of claim 1, wherein the cleaning step includes applying the second ultraviolet laser beam selectively to the microelectronic device while leaving a surrounding area of the second substrate unexposed to the second ultraviolet laser beam.

19. A method for ultraviolet-laser transfer and cleaning of microelectronic devices, comprising steps of:
transferring a microelectronic device from a first substrate to a second substrate, said transferring including laser ablating a sacrificial layer coupling the microelectronic device to the first substrate, the sacrificial layer containing gallium, said laser ablating leaving a gallium residue on the microelectronic device;
cleaning at least a portion of the gallium residue off the microelectronic device after the transferring step, said cleaning including laser ablating the gallium residue with a second ultraviolet laser beam; and
generating the first and second ultraviolet laser beams with the same ultraviolet laser.
